(19) United States
(12) Patent Application Publication
(10) Pub. No.: US 2026/0060125 A1
(43) Pub. Date: Feb. 26, 2026

(54) SUBSTRATE ARRANGEMENT, METHOD FOR PRODUCING AN ELECTRONIC ASSEMBLY, AND ELECTRONIC ASSEMBLY

(71) Applicant: Heraeus Electronics GmbH & Co. KG, Hanau (DE)

(72) Inventors: Jürgen SCHARF, Hanau (DE); Frank KRÜGER, Hanau (DE); Vemal RAJA MANIKAM, Hanau (DE)

(21) Appl. No.: 19/302,649

(22) Filed: Aug. 18, 2025

(30) Foreign Application Priority Data
Aug. 23, 2024 (EP) 24196058.2

(51) Int. Cl. H01L 23/00

(52) U.S. Cl. CPC H01L 24/29; H01L 24/83; H01L 2224/29083; H01L 2224/29139; H01L 2224/29147; H01L 2224/8384

(57) ABSTRACT

The invention relates to a substrate arrangement, to a method for producing an electronic assembly and to an electronic assembly. The substrate arrangement comprises (a) a metal foil comprising an upper side and an underside, (b) a silver layer arranged on the underside of the metal foil, and (c) a silver sinter layer arranged on the silver layer, wherein the silver layer has a thickness d(Ag) in the range of 20-1500 nm.

### CROSS-REFERENCE TO RELATED APPLICATION

This application claims priority pursuant to 35 U.S.C. 119 (a) to European Patent Office Application No. 24196058.2, filed Aug. 23, 2024, which application is incorporated herein by reference in its entirety.

### FIELD

The present invention relates to a substrate arrangement, to a method for producing an electronic assembly and to an electronic assembly.

### BACKGROUND

In order to produce electronic assemblies, base substrates, in particular metal-ceramic substrates or lead frames, are often populated with electronic components, in particular semiconductor devices, in the field of power electronics.

Regions which have to be contacted electrically conductively with unpopulated regions of the base substrates are located on the upper side of the electronic components, which faces away from the base substrates. This contact usually takes place with bonding wires, wherein one end of the bonding wire is integrally bonded to a region on the upper side of the electronic component, while the other end of the bonding wire is integrally bonded to an unpopulated region of the base substrate. Bonding wires made of aluminum can be integrally bonded to the metal of the base substrates, in particular copper. Bonding wires made of aluminum, for example via a metal, usually silver-containing layer which is located on the upper side of the electronic components, can also be integrally bonded to the electronic components. However, bonding wires made of aluminum have the disadvantage of low electrical conductivity. Furthermore, it has been found that electrical contacting of electronic components and base substrates via bonding wires made of aluminum has only insufficient reliability and reduced functionality.

For this reason, there is a need to replace aluminum bonding wires with bonding wires made of copper. Copper has a very high electrical conductivity compared to aluminum. Furthermore, bonding wires made of copper can be connected particularly reliably in an integrally bonded manner to the metal of the base substrates, in particular copper. However, bonding wires made of copper cannot easily be connected to the upper side of the electronic components in an integrally bonded manner.

In the prior art, it is therefore proposed that bonding wires made of copper are not to be connected directly to the upper side of the electronic components. Instead, a substrate arrangement is provided which comprises a metal foil and a silver sinter layer. The metal foil has an upper side and an underside, wherein the underside of the metal foil is bonded in a planar manner to the silver sinter layer, usually a pre-dried sintering paste. The metal foil of the substrate arrangement is finally integrally bonded to the upper side of the electronic component via the silver sinter layer, so that the upper side of the metal foil is available for an integrally bonded connection to the copper bonding wire. To ensure a secure connection of the bonding wire to the upper side of the electronic component via a substrate arrangement, it is necessary that the integrally bonded connection created via the silver sinter layer between the underside of the metal foil and the upper side of the electronic component has a high adhesive strength.

Before the integrally bonded connection is formed, the silver sinter layer should also be sufficiently firmly connected to the metal foil of the substrate arrangement. However, it has been found that in substrate arrangements the silver sinter layer, usually a pre-dried sintering paste, only forms an insufficient bond with the metal foil. To improve the bond, it has been proposed to provide the metal foil with a gold layer, which makes possible an improved adhesion of the silver sinter layer. However, bonding a gold layer to the metal foil is not easily possible, so that a multi-layer structure has been proposed, which includes, for example, the metal foil, a nickel layer in contact therewith, a palladium layer in contact with the nickel layer and a gold layer in contact with the palladium layer. This layer structure is very complex to produce.

### SUMMARY

There is still a need for a substrate arrangement in which the metal foil has a strong bond with the silver sinter layer and which is capable of creating an integrally bonded connection with high adhesive strength between the underside of the metal foil and the upper side of an electronic component.

For this reason, one object of the present invention is preferably to provide a substrate arrangement in which the metal foil has a strong bond with the silver sinter layer and which is capable of creating an integrally bonded connection with high adhesive strength between the underside of the metal foil and the upper side of an electronic component.

This object is achieved by the substrate arrangement according to claim 1.

The invention therefore provides a substrate arrangement comprising
(a) a metal foil comprising an upper side and an underside;
(b) a silver layer arranged on the underside of the metal foil; and,
(c) a silver sinter layer arranged on the silver layer, wherein the silver layer has a thickness d (Ag) in the range of 20-1500 nm.

The invention further provides a method for producing an electronic assembly, and an electronic component.

The invention relates to a substrate arrangement.

The electrical contacting of the upper side of an electronic component with unpopulated regions of base substrates can preferably be prepared with the substrate arrangement. For this purpose, the metal foil is connected in an integrally bonded manner to the upper side of the electronic component via the silver sinter layer. The metal foil in this case provides a surface which is suitable for forming a reliable integrally bonded connection to one end of a bonding wire, particularly a copper bonding wire. The other end of the bonding wire can be connected to an unpopulated region of a base substrate, so that an electrical contacting results between the upper side of the electronic component and an unpopulated region of a base substrate via the metal foil and the bonding wire.

The substrate arrangement has a metal foil.

The metal foil comprises an upper side and an underside. A silver layer is arranged on the underside of the metal foil. The underside of the metal foil is preferably connected in a planar manner to the silver layer, at least in regions. The underside of the metal foil is therefore preferably the surface of the metal foil with the greatest surface area which is connected in a planar manner to the silver layer at least in regions. The upper side of the metal foil is therefore preferably the side of the metal foil facing away from the silver sinter layer. The upper side of the metal foil is consequently the side opposite the underside of the metal foil.

According to a preferred embodiment, the upper side of the metal foil does not form an integrally bonded connection with a solid body. A solid body is preferably a body that is solid at a temperature of 25° C. and normal pressure. Preferably, the upper side of the metal foil does not form an integrally bonded connection with a layer of insulating material. Particularly preferably, the upper side of the metal foil does not form an integrally bonded connection with a ceramic layer.

According to a further preferred embodiment, less than 20 percent, more preferably less than 10 percent, even more preferably less than 5 percent, most preferably less than 1 percent and in particular less than 0.1 percent of the upper side of the metal foil, based on the total surface of the upper side of the metal foil, is inseparably bonded to a solid body. Inseparably bonded preferably means that a release of the connection is not possible or would result in at least partial destruction of the upper side of the metal foil, or at least a functional impairment. The solid body can be a solid body comprising insulating material, in particular a ceramic body.

According to a further preferred embodiment, the upper side of the metal foil can be connected to a bonding wire, preferably a bonding wire comprising at least 50 percent by weight of copper.

The metal foil preferably has a thickness d(Me). The thickness d(Me) of the metal foil is preferably in the range of 5-500 μm, particularly preferably in the range of 10-200 μm and very particularly preferably in the range of 20-150 μm.

The metal foil preferably comprises at least one element which is selected from the group consisting of metals and metal alloys. The metal foil preferably comprises at least 99.5% by weight of metal, particularly preferably at least 99.95% by weight of metal, and very particularly preferably at least 99.995% by weight of metal, based on the total weight of the metal foil. According to a further preferred embodiment, the metal foil comprises at least one element which is selected from the group consisting of copper and copper alloys. It may be preferred here that copper alloys are alloys of copper with at least one further metal selected from the group consisting of nickel, tin, iron, silver, tungsten, and molybdenum. According to a particularly preferred embodiment, the metal foil comprises copper. According to a particularly preferred embodiment, the metal foil is a copper foil. The copper foil preferably comprises at least 99.5% by weight of copper, particularly preferably at least 99.95% by weight of copper, and very particularly preferably at least 99.995% by weight of copper, based on the total weight of the copper foil.

The substrate arrangement has a silver layer.

The silver layer comprises silver. The silver layer is preferably a layer consisting of silver or a silver-containing alloy, particularly preferably silver. The silver content is preferably at least 70 percent by weight, more preferably at least 95 percent by weight, particularly preferably at least 99 percent by weight, very particularly preferably at least 99.9 percent by weight and in particular at least 99.99 percent by weight, based on the total weight of the silver layer.

The silver layer is arranged on the underside of the metal foil.

The silver layer is preferably connected in a planar manner to the underside of the metal foil at least in regions. The silver layer is preferably connected to the underside of the metal foil in a planar manner such that at least 75%, more preferably at least 90%, particularly preferably at least 95%, very particularly preferably at least 98% and in particular 100%, of the area occupied by the underside of the metal foil is provided with silver layer.

According to a preferred embodiment, the silver layer on the underside of the metal foil is created by deposition.

The silver layer on the underside of the metal foil is preferably created by chemical (e.g. electrochemical) or physical deposition. The chemical deposition of the silver layer can be carried out, for example, galvanically or without external current. Preferably, the chemical deposition of the silver layer is carried out without external current, in particular by applying a silver-containing solution as a result of a charge exchange between the metals, wherein metal of the metal foil partially dissolves while the silver in the solution is deposited. According to a preferred embodiment, the silver-containing solution contains a silver salt and particularly preferably silver nitrate. According to a particularly preferred embodiment, the silver-containing solution is an acidic solution of silver nitrate, and particularly preferably a nitric acid solution of silver nitrate. The concentration of silver in the nitric acid solution can, for example, be in the range of 0.5-1.5 g/l, particularly preferably in the range of 0.6-1.4 g/l and most preferably in the range of 0.8-1.2 g/l. The physical deposition of the silver layer can be carried out, for example, by gas phase deposition. Preferred methods for gas phase deposition are in particular electron beam deposition, laser beam deposition, arc discharge deposition or cathodic sputtering. According to a particularly preferred embodiment, the silver layer on the underside of the metal foil is created by deposition without external current.

The silver layer has a thickness d (Ag). The thickness d (Ag) of the silver layer is in the range of 20-1500 nm. The thickness d (Ag) of the silver layer is preferably in the range of 50-1200 nm, particularly preferably in the range of 100-1000 nm and very particularly preferably in the range of 200-800 nm. The thickness d (Ag) of the silver layer can be determined in a conventional manner, for example by X-ray fluorescence spectrometry or by X-ray electron microscopy of a representative cross-section perpendicular to the upper side of the metal foil.

Surprisingly, it was found that the inventive design of the substrate arrangement brings about a well-developed connection between the metal foil and the silver sinter layer and, moreover, enables the formation of an integrally bonded connection with high adhesive strength between the metal foil and the upper side of an electronic component. Without being bound to theory, this could be due to the special design of the silver layer applied between the metal foil and the silver sinter layer, which according to the invention has a thickness d (Ag) in the range of 20-1500 nm. On the one hand, such a silver layer seems to ensure sufficient and reliable coverage of the underside of the metal foil, so that the silver sinter layer is separated from the underside of the metal foil by the silver layer. The silver layer could function as a reliable adhesion promoter between the silver sinter layer and the underside of the metal foil. On the other hand, the silver layer appears to be sufficiently thin so that it does not act as a diffusion barrier but rather promotes diffusion of the metal of the metal foil through the silver layer toward the upper side of the electronic component when an integrally bonded connection is formed between the upper side of an electronic component and the substrate arrangement, thus contributing significantly to the high adhesive strength.

According to a preferred embodiment, the ratio R=d(Ag)/d(Me), i.e. the ratio between the thickness of the silver layer d (Ag) and the thickness of the metal foil d (Me), is less than 0.05, more preferably less than 0.02, particularly preferably less than 0.01 and most preferably less than 0.005.

Preferably, the ratio R=d(Ag)/d(Me) is at least 0.0001, particularly preferably at least 0.0005 and very particularly preferably at least 0.001.

The ratio R=d(Ag)/d(Me) is preferably in the range of 0.0001-0.02, particularly preferably in the range of 0.0005-0.01 and very particularly preferably in the range of 0.001-0.005.

According to a further preferred embodiment, the arrangement comprising the metal foil and the silver layer arranged on the underside of the metal foil has at least one through-opening. A through-opening is preferably understood to mean a recess in the material of the metal foil and silver layer which extends from a first opening on the upper side of the metal foil up to a second opening on the silver layer. The openings can have different sizes and geometries. It may be preferable for the arrangement to have a plurality of through-openings. The through-openings can, for example, be cylindrical, round, rectangular, oval, elliptical or rectangular with rounded corners. The presence of through-openings can be advantageous in particular if the substrate arrangement comprises a prefixing layer which contains a prefixing agent. In this case, components or residues of the prefixing agent can liquefy during a temperature application or pressure application, such as during a sintering process, and can be absorbed into the through-openings due to the capillary effect caused by the through-opening in order thereby to prevent an uncontrollable escape from the portions or residues of the prefixing agent.

The substrate arrangement has a silver sinter layer.

The silver sinter layer is preferably a layer capable of entering into an integrally bonded connection with an electronic component, in particular the optionally metallized upper side of an electronic component.

The silver sinter layer comprises silver.

The silver sinter layer preferably comprises silver and organic compounds. The proportion of silver in the silver sinter layer is preferably at least 50 percent, more preferably at least 75 percent, particularly preferably at least 85 percent and most preferably at least 90 percent, based on the total weight of the silver sinter layer. The proportion of organic compounds is preferably less than 50 percent, more preferably less than 25 percent, particularly preferably less than 15 percent and most preferably less than 10 percent, based on the total weight of the silver sinter layer.

The silver sinter layer is arranged on the silver layer.

The silver sinter layer is a layer that is connected in a planar manner to the silver layer, at least in regions. According to a preferred embodiment, the silver sinter layer is connected in a planar manner to the silver layer in such a way that at least 75%, more preferably at least 90%, particularly preferably at least 95%, very particularly preferably at least 98% and in particular 100% of the surface of the silver layer facing away from the underside of the metal foil is provided with a silver sinter layer and, if appropriate, an optionally present prefixing layer.

The silver sinter layer preferably has a thickness in the range of 5-500 μm, particularly preferably a thickness in the range of 5-100 μm, and very particularly preferably a thickness in the range of 10-50 μm.

According to a preferred embodiment, the silver sinter layer comprises a sintering material. The sintering material is preferably selected from the group consisting of sintering pastes, sintering films and sintering preforms.

According to a preferred embodiment the sintering material comprises a sintering paste. Sintering paste is preferably a sintering paste customary in the art. The sintering paste preferably comprises silver and organic compounds. It may be preferred for silver in the sintering paste to be present in the form of particles. The particles can assume any shape and can therefore be present, for example, as spherical particles, flakes or irregularly shaped particles. The organic compounds are preferably selected from the group consisting of dispersants, binders, fatty acids, and mixtures thereof. The dispersant can be selected from dispersants that are customary in the art. An exemplary dispersant is terpineol. The binders can be selected from polymers that are customary in the art. Examples include cellulose derivatives, for example methylcellulose, ethylcellulose, ethylmethylcellulose, carboxycellulolose and hydroxypropylcellulolose. The fatty acids can be selected from fatty acids that are customary in the art. The fatty acids are preferably selected from the group consisting of caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), arachidic acid (eicosanoic acid/icosanoic acid), behenic acid (docosanoic acid) and lignoceric acid (tetracosanoic acid). The sintering paste is preferably pre-dried. In this case, the silver sinter layer comprises a pre-dried sintering paste. The pre-drying can serve to at least partially remove volatile constituents contained in the sintering paste, such as organic compounds, for example. The pre-drying can take place, for example, at a temperature in the range of 80-150° C. and, for example, for a period of 2-30 minutes.

According to a further preferred embodiment, the sintering material comprises a sintering film. Preferably, the sintering film is a sintering film customary in the art, as disclosed, for example, in European patent application EP3154729 A1. A sintering film can therefore comprise, for example, a sintering paste which contains silver particles and organic compounds (such as a binder) which is present in a pre-dried state on a carrier substrate. The sintering film can, for example, have a thickness ranging from 5-300 μm.

According to a further preferred embodiment, the sintering material comprises a sintering preform. Preferably, the sintering preform is a conventional sintering preform as disclosed, for example, in European patent application EP2428293 A2.

According to a particularly preferred embodiment, the silver sinter layer comprises a pre-dried sintering paste.

The silver layer and the silver sinter layer can be visually distinguished from one another. Particularly preferably, a distinction between silver layer and silver sinter layer is made using an electron micrograph (for example an X-ray electron micrograph). The silver sinter layer preferably has a higher porosity and thus a lower density than the silver layer.

According to a preferred embodiment, the substrate arrangement comprises a prefixing layer.

The prefixing layer is preferably a layer which is connected to at least one further layer. The at least one further layer is preferably at least one layer selected from the group consisting of the silver layer and the silver sinter layer. The prefixing layer can be, for example, a continuous layer or an interrupted layer. The dimension of the continuous layer is not further limited. For this reason, the continuous layer also comprises a punctiform layer. In the case of a continuous layer, the prefixing layer can be connected to the at least one further layer in a planar manner. In the case of an interrupted layer, the prefixing layer can comprise a plurality of portions which are not in contact with one another and which are connected in a planar manner to the at least one further layer. The at least one further layer is preferably the silver layer or the silver sinter layer. According to a preferred embodiment, the prefixing layer is a layer which is connected (i) to the silver layer, (ii) to the silver sinter layer or (iii) to the silver layer and the silver sinter layer. If the prefixing layer is connected to the silver layer, the silver sinter layer is connected in a planar manner to the silver layer preferably at least in regions, and the prefixing layer is connected to regions of the silver layer which are not connected in a planar manner to the silver sinter layer. In such a case, the silver sinter layer and the prefixing layer are each connected to the silver layer and are preferably arranged next to one another.

According to a preferred embodiment, the prefixing layer is formed as a continuous layer and is connected in a planar manner to the silver sinter layer so that at least 20%, more preferably at least 50%, particularly preferably at least 70%, very particularly preferably at least 98% and in particular 100% of the silver sinter layer is in contact with the prefixing layer.

According to a further preferred embodiment, the prefixing layer is formed as a continuous layer in a punctiform manner and is in contact with the silver sinter layer and/or with the silver layer.

According to a further preferred embodiment, the prefixing layer is formed as an interrupted layer comprising a plurality of portions which are not in contact with one another and which are in contact with the silver sinter layer and/or with the silver layer.

The prefixing layer preferably comprises a prefixing agent. The prefixing agent can serve to prefix the substrate arrangement on an electronic component so that the structure comprising the substrate arrangement and the electronic component has improved transportability—for example, at the location of the further processing. Preferably, the prefixing agent is a temporary or releasable fixing agent which allows at least a temporary fixing of the substrate arrangement to an electronic component. Suitable prefixing agents are described, for example, in European patent application EP3940758 A2.

The prefixing agent therefore preferably comprises at least one compound which is selected from the group consisting of thermoplastic polymers, inorganic filler particles, and organic solvents. According to a preferred embodiment, the prefixing agent comprises at least one thermoplastic polymer and particularly preferably at least one compound which is selected from the group consisting of inorganic filler particles and organic solvents.

The thermoplastic polymers preferably have a glass transition temperature in the range of 60-120° C. The glass transition temperature is preferably determined by means of dynamic differential calorimetry (DDC) or by means of differential scanning calorimetry (DSC) at a heating rate of 10° C./minute. The thermoplastic polymers can in particular be (meth)acrylic copolymers. The (meth)acrylic copolymers preferably have a molar mass in the range of 35 000-70 000 g/mol (Mw=35 000 to 70 000 g/mol). The molar mass is preferably determined by means of gel permeation chromatography (GPC). For the gel permeation chromatography, the following applies: polystyrene gel as stationary phase, tetrahydrofuran as mobile phase, polystyrene standards.

The inorganic filler particles are preferably particles comprising at least one element selected from the group consisting of aluminum oxide, silicon dioxide, titanium dioxide, zirconium silicate, calcium silicate, mica, kaolin, and α-boron nitride. The inorganic filler particles preferably have an average particle size (d50) in the range of 5-20 μm and particularly preferably in the range of 5-10 μm. The average particle size (d50) is preferably determined by means of a laser diffraction method.

The organic solvents preferably have a boiling point of not more than 285° C. According to a preferred embodiment, the organic solvents are selected from the group consisting of aromatics, ketones, esters, glycol ethers and alcohols. According to a particularly preferred embodiment, the organic solvents are selected from the group consisting of toluene, xylene, methyl ethyl ketone, methyl isobutyl ketone, ethyl acetate, isobutyl acetate, dimethyl succinate, diethylene glycol monobutyl ether, benzyl alcohol, and terpincols. According to a very particularly preferred embodiment, the organic solvents are selected from the group of terpincols.

According to a preferred embodiment, the substrate arrangement is suitable for connection to at least one electronic component. According to a particularly preferred embodiment, the substrate arrangement is suitable for connecting the metal foil to at least one electronic component.

An electronic component is preferably understood to mean an electronic or electrical part. The electronic component is preferably selected from the group consisting of semiconductor devices. The semiconductor devices are preferably selected from the group consisting of transistors, diodes, and integrated circuits.

According to a preferred embodiment, the electronic component comprises a metal upper-side coating. The metal upper-side coating can serve to make possible an easier connection of the metal foil via the silver sinter layer to the upper side of the electronic component. It may therefore be preferred that the upper side of the electronic component is created by the metal upper-side coating. The metal upper-side coating of the electronic component preferably comprises at least one element which is selected from the group consisting of nickel, palladium, silver and gold. According to a preferred embodiment, the electronic component comprises a metal underside coating. The metal underside coating can serve to enable an easier connection of the base substrate to the underside of the electronic component. It may therefore be preferred that the underside of the electronic component is created by the metal underside coating. The metal underside coating of the electronic component preferably comprises at least one noble metal. According to a preferred embodiment, the metal underside coating of the electronic component comprises at least one element which is selected from the group consisting of gold, silver, aluminum, titanium, and nickel, and very particularly preferably silver.

The electrical contacting of the upper side of the electronic component with unpopulated regions of base substrates can preferably be prepared with the substrate arrangement. For this purpose, the metal foil is connected in an integrally bonded manner to the upper side of the electronic component via the silver sinter layer. The metal foil provides a surface which is suitable for the integrally bonded connection to a bonding wire, in particular a copper bonding wire, in a particularly stable manner.

The method for producing the substrate arrangement according to the invention is not further limited.

According to a preferred embodiment, the method for producing the substrate arrangement according to the invention comprises the steps of:
(A) providing a metal foil that comprises an upper side and an underside;
(B) creating a silver layer arranged on the underside of the metal foil, wherein the silver layer has a thickness d (Ag) in the range of 20-1500 nm; and,
(C) creating a silver sinter layer arranged on the silver layer.

In step (A) of the method, a metal foil is provided.

The metal foil is preferably a metal foil as described elsewhere herein.

In step (B), a silver layer is created which is arranged on the underside of the metal foil, wherein the silver layer has a thickness d (Ag) in the range of 20-1500 nm.

The silver layer arranged on the underside of the metal foil is preferably created by deposition. The deposition is preferably carried out chemically (e.g. electrochemically) or physically. The chemical deposition of the silver layer can be carried out, for example, galvanically or without external current. Preferably, the chemical deposition of the silver layer is carried out without external current, in particular by applying a silver-containing solution as a result of a charge exchange between the metals, wherein metal of the metal foil partially dissolves while the silver in the solution is deposited. According to a preferred embodiment, the silver-containing solution contains a silver salt and particularly preferably silver nitrate. According to a particularly preferred embodiment, the silver-containing solution is an acidic solution of silver nitrate, and particularly preferably a nitric acid solution of silver nitrate. The concentration of silver in the nitric acid solution can, for example, be in the range of 0.5-1.5 g/l, particularly preferably in the range of 0.6-1.4 g/l and most preferably in the range of 0.8-1.2 g/l. The physical deposition of the silver layer can be carried out, for example, by gas phase deposition. Preferred methods for gas phase deposition are in particular electron beam deposition, laser beam deposition, arc discharge deposition or cathodic sputtering. According to a particularly preferred embodiment, the silver layer on the underside of the metal foil is created by deposition without external current.

In step (C), a silver sinter layer is created which is arranged on the silver layer.

For this purpose, a sintering material is preferably provided. The silver material is preferably selected from the group consisting of sintering pastes, sintering films and sintering preforms. The sintering material is preferably a sintering material as described elsewhere herein.

The sintering material is preferably applied to the silver layer. Application of the sintering material to the silver layer to form a silver sinter layer can be carried out by methods customary in the art, depending on the form in which the sintering material is provided (for example as sintering paste, sintering foil and/or sintering preform). Preferably, the sintering material is applied by jetting, dispensing, spraying, brushing, dabbing, dipping, applying, pressing or printing, in particular screen printing or stencil printing.

According to a preferred embodiment, in a further step (D) a prefixing agent is applied to the silver sinter layer and/or the silver layer to form a prefixing layer. The prefixing agent is preferably a prefixing agent as described elsewhere herein. The prefixing agent can be applied to the silver sinter layer and/or silver layer by methods customary in the art. Preferably, the prefixing agent is applied by jetting, dispensing, spraying, brushing, dabbing, dipping or printing, in particular screen printing or stencil printing.

According to a preferred embodiment, pre-drying takes place in a further step (E) of the method. The pre-drying can serve to at least partially remove volatile constituents, such as organic compounds, contained in the sintering material and, if present, in the prefixing agent. The pre-drying can take place, for example, at a temperature in the range of 80-150° C. and, for example, for a period of 2-30 minutes. The pre-drying usually results in a volume shrinkage, so that the thickness of the initially created silver sinter layer and, if present, of the initially created prefixing layer is also reduced.

According to a further embodiment, it is possible that the application of a prefixing agent to the silver sinter layer and/or silver layer to form a prefixing layer (according to step D) takes place after the pre-drying (according to step E).

In the method, a substrate arrangement is obtained with which the metal foil can be connected in a particularly stable and integrally bonded manner to the upper side of an electronic component via the silver sinter layer.

The invention relates to a method for producing an electronic assembly.

The method comprises the following steps:
(A) providing a base substrate that comprises an upper side, wherein the base substrate comprises a metal layer;
(B) providing an electronic component that comprises an upper side and an underside;
(C) providing a substrate arrangement described herein;
(D) contacting the upper side of the base substrate with the underside of the electronic component, forming an integrally bonded connection; and,
(E) contacting the upper side of the electronic component with the silver sinter layer of the substrate arrangement to form an integrally bonded connection.

In step (A) of the method, a base substrate is provided. The base substrate comprises a metal layer. Furthermore, the base substrate has an upper side.

For example, the metal layer of the base substrate can comprise copper. Preferably, the metal layer of the base substrate can be formed from a metal foil. According to a preferred embodiment, the metal layer of the base substrate comprises a copper foil.

According to a preferred embodiment, the base substrate consists of the metal layer.

According to another preferred embodiment, the base substrate comprises a metal layer and a layer of insulating material. According to a further preferred embodiment, the base substrate comprises a metal layer and a layer of insulating material which are connected to one another in an integrally bonded manner. The base substrate preferably comprises a layer of insulating material which, on the first side and a second side facing away from the first side, is connected in an integrally bonded manner to a metal layer.

The insulating material of the base substrate is preferably selected from the group consisting of glass and ceramic. The ceramic can, for example, be selected from the group consisting of oxide ceramics, nitride ceramics, and carbide ceramics.

According to a preferred embodiment, the base substrate is selected from the group consisting of metal-ceramic substrates, printed circuit boards (PCBs) and leadframes. According to a particularly preferred embodiment, the base substrate is a metal-ceramic substrate customary in the art. The metal-ceramic substrate is preferably selected from the group consisting of DCB (direct copper bonded) substrates and AMB (active metal brazed) substrates.

The upper side of the base substrate is preferably created by the metal layer.

In step (B) of the method, an electronic component is provided. The electronic component has an upper side and an underside.

The electronic component is preferably an electronic component as described elsewhere herein. In step (C) of the method, a substrate arrangement is provided.

The substrate arrangement is preferably a substrate arrangement as described elsewhere herein.

The substrate arrangement therefore preferably has
(a) a metal foil comprising an upper side and an underside;
(b) a silver layer arranged on the underside of the metal foil, wherein the silver layer has a thickness d (Ag) in the range of 20-1500 nm; and,
(c) a silver sinter layer arranged on the silver layer.

In step (D) of the method, the upper side of the base substrate is contacted with the underside of the electronic component, forming an integrally bonded connection.

For this purpose, the base substrate and the electronic component are preferably positioned such that the underside of the electronic component is in contact with the upper side of the base substrate preferably via a contacting material. The contacting means can be, for example, a sintering paste, a soldering paste or a conductive adhesive. The structure comprising the base substrate and the electronic component is subsequently subjected to a treatment which allows an integrally bonded connection through the contacting material. The underside of the electronic component is fastened here to the upper side of the base substrate. The treatment is preferably carried out by introducing energy. The introduction of energy can preferably take place in the form of temperature application and particularly preferably in the form of temperature and pressure application.

In step (E) of the method, the upper side of the electronic component is contacted with the silver sinter layer of the substrate arrangement to form an integrally bonded connection. In this case, the formation of an integrally bonded connection is preferably carried out between the upper side of the electronic component and the metal foil of the substrate arrangement.

For this purpose, the substrate arrangement and the electronic component are preferably positioned such that the silver sinter layer of the substrate arrangement is in contact with the upper side of the electronic component. The structure comprising the substrate arrangement and the electronic component is subsequently subjected to a treatment which allows an integrally bonded connection through the silver sinter layer. The metal foil of the substrate arrangement is fastened here to the upper side of the electronic component. The treatment is preferably carried out by introducing energy. The introduction of energy can preferably take place in the form of temperature application and particularly preferably in the form of temperature and pressure application.

As a result of the temperature application, a diffusion zone preferably forms between the metal foil and the bonding zone created by the integrally bonded connection between the metal foil and the upper side of the electronic component. The diffusion zone preferably extends from the metal foil perpendicular to the metal foil toward the upper side of the electronic component. The diffusion zone preferably has a width in the range of 0.5 μm-3.0 μm and particularly preferably a width in the range of 0.8 μm-2.0 μm. The diffusion zone preferably comprises at least portions of the metal foil, silver layer and bonding zone. The thickness of the diffusion zone can be measured, for example, by scanning electron microscopy-energy-dispersive X-ray spectroscopy (SEM-EDX). For this purpose, a cut through the electronic assembly is preferably made perpendicular to the metal foil. The cut surface is preferably scanned under a scanning electron microscope in a line scan, and the element distribution is measured by means of SEM-EDX. The element signals (in cps, counts per second) can then be determined as a function of the measuring length (in μm). The element distribution curves thus obtained can then be evaluated. The diffusion zone preferably extends from an initial drop in the copper signal to a value of approximately 0 cps (noise floor). Surprisingly, it was found that diffusion of metal from the metal layer beyond the silver layer toward the upper side of the electronic component can significantly increase the adhesive strength of the integrally bonded connection.

Steps (D) and (E) can be carried out in one manufacturing step or in different manufacturing steps. In this case, steps (D) and (E) can be carried out sequentially or simultaneously.

If steps (D) and (E) are carried out sequentially, step (D) can take place before step (E). On the other hand, it is also possible for step (E) to take place before step (D).

If steps (D) and (E) are carried out sequentially, according to a first embodiment in step (D) the electronic component can be part of a first arrangement which comprises the electronic component and the metal foil of the substrate arrangement. In this case, a first arrangement, which comprises the electronic component and the metal foil of the substrate arrangement, can first be produced in step (E) by contacting the upper side of the electronic component with the metal foil of the substrate arrangement to form an integrally bonded connection between the upper side of the electronic component and the metal foil of the substrate arrangement. This first arrangement can then be contacted with the base substrate in step (D) so that the underside of the electronic component is connected in an integrally bonded connection to the upper side of the base substrate as part of the first arrangement.

If steps (D) and (E) are carried out sequentially, according to a second embodiment in step (E) the electronic component can be part of a second arrangement which comprises the base substrate and the electronic component. In this case, a second arrangement which comprises the base substrate and the electronic component can first be produced in step (D). This second arrangement can then be contacted with the substrate arrangement in step (E) so that the metal foil of the substrate arrangement is connected in an integrally bonded manner to the upper side of the electronic component as part of the second arrangement.

By means of the integrally bonded connection of the base substrate, electronic component and metal foil of the substrate arrangement, an electronic assembly is obtained.

The electronic assembly is characterized by a pronounced diffusion zone. The diffusion zone preferably extends from the metal foil perpendicular to the metal foil toward the upper side of the electronic component. The diffusion zone preferably has a width in the range of 0.5 μm-3.0 μm and particularly preferably a width in the range of 0.8 μm-2.0 μm. The diffusion zone preferably comprises at least portions of the metal foil, silver layer and bonding zone. The thickness of the diffusion zone can be measured as described above, for example by scanning electron microscopy-energy-dispersive X-ray spectroscopy (SEM-EDX).

According to a preferred embodiment, in a further step (F) a region on the upper side of the metal foil is electrically contacted with a region on the upper side of the base substrate. The electrical contacting preferably takes place by wire bonding. A bonding wire is preferably used for wire bonding. The bonding wire preferably comprises copper. According to a preferred embodiment, the bonding wire is made of a material selected from the group consisting of copper and copper alloys.

### BRIEF DESCRIPTION OF THE DRAWINGS

Further features and advantages of the invention can be found in the following description of the figures, in which preferred embodiments of the invention are explained with reference to schematic drawings. In the drawings:

FIG. 1 shows the side view of a substrate arrangement according to the invention; and,

FIG. 2 shows the side view of an electronic assembly which is obtained by the method according to the invention.

### DETAILED DESCRIPTION OF THE INVENTION

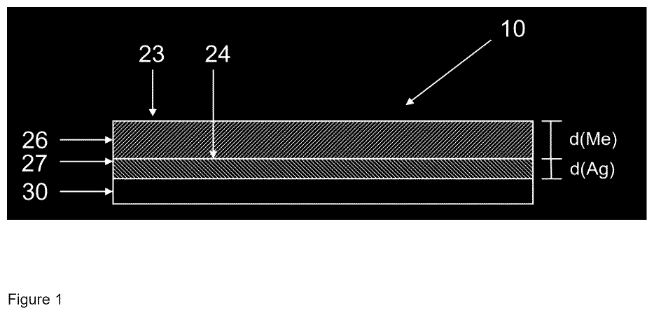

FIG. 1 shows—not to scale—a substrate arrangement 10 according to the invention, which comprises a metal foil 26, a silver layer 27 and a silver sinter layer 30. The metal foil 26 has an upper side 23 and an underside 24. The metal foil 26 has a thickness d (Me). The silver layer 27 is arranged on the underside 24 of the metal foil 26. The silver layer 27 has a thickness d (Ag) in the range of 20-1500 nm. The silver sinter layer 30 is arranged on the silver layer 27.

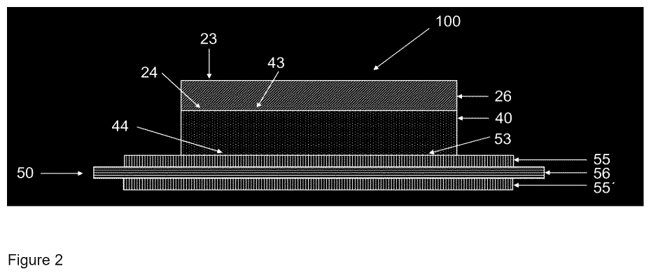

FIG. 2 shows an electronic assembly 100 which can be produced by the method according to the invention. The electronic assembly 100 comprises a metal foil 26, an electronic component 40, and a base substrate 50. The base substrate 50 has a layer of insulating material 56 which is connected on both sides to a metal layer 55, 55′ in a planar manner. The base substrate 50 is typically a metal-ceramic substrate. The upper side 53 of the base substrate 50 is created by the metal layer 55. An electronic component 40, which has an upper side 43 and an underside 44, is arranged on the upper side 53 of the base substrate 50. The underside 44 of the electronic component 40 is arranged on the upper side 53 of the base substrate 50. The electronic component 40 is connected to the base substrate 50 in a planar manner. For this purpose, the electronic component 40 can be fastened to the base substrate 50, for example using a sintering paste. A bonding zone (not shown) can therefore be located between the upper side 53 of the base substrate 50 and the underside 44 of the electronic component 40. The electronic component 40 is connected to a metal foil 26 via a bonding zone (not shown). The metal foil 26 has an upper side 23 and an underside 24. The underside 24 of the metal foil 26 is arranged on the upper side 43 of the electronic component 40. The metal foil 26 is fastened to the electronic component 40. Fastening takes place by first positioning a substrate arrangement, comprising the metal foil 26, a silver layer and a silver sinter layer, on the upper side 43 of the electronic component 40 such that the silver sinter layer is in contact with the upper side 43 of the electronic component 40. The structure thus obtained is then exposed to conditions which enable the formation of an integrally bonded connection between the metal foil 26 and the electronic component 40. The silver sinter layer can consist, for example, of a pre-dried sintering paste. In this case, the structure is subjected, for example, to temperature and pressure to enable the formation of a sintered connection between the metal foil 26 and the electronic component 40. During the formation of the sintered connection, the bonding zone is created between the metal foil 26 and the electronic component 40 by the silver layer and the silver sinter layer (not shown). The upper side 23 of the metal foil 26 can be contacted with a bonding wire with unpopulated regions on the upper side 53 of the base substrate 50 (not shown). The upper side 23 of the metal foil 26 can also be connected in an integrally bonded manner to a further component, using a sintering material (not shown).

### EXAMPLES

The present invention is further illustrated below using examples which are, however, not to be understood as limiting.

### 1. Production of Substrate Arrangements

Copper foils having a thickness of 50 μm were used to produce a substrate arrangement according to the Examples and the Comparative Examples. They were arranged on a transfer film made of plastic and stretched into a frame. The supported copper foils were structured by means of photolithographic etching using a suitable masking with an iron chloride (FeCl₃) etching solution into copper foil pieces of dimensions 7.6 mm×7.6 mm, wherein the individual copper foil pieces were still connected to one another via webs. The masking was then removed.

The copper foil pieces thus obtained were cleaned using a commercially available aqueous cleaning agent and rinsed with water. The surface of the copper foil pieces was then freed from oxides by contacting them with an aqueous sodium peroxodisulfate solution (concentration=50 g/l). The copper foil pieces treated in this way were then cleaned again with a commercially available aqueous cleaning agent and rinsed with water.

The copper foil pieces pretreated in this way were then provided with a coating as described below.

### 1.1 Example 1

The pretreated copper foil pieces were placed in a pre-immersion solution containing nitric acid and a complexing agent at a temperature of 45° C. for 30 s. The copper foil pieces were then directly immersed in a nitric acid silver nitrate solution (silver content=1.0 g/l) at a temperature of 55° C. The immersion time was 200 s. This resulted in copper foil pieces with a silver layer arranged on the underside, which had a thickness of 203 nm.

A silver sinter layer was then applied to the silver layer. For this purpose, a sintering paste (ASP 043-60, Heraeus) was applied by means of stencil printing to a region of 7.1 mm×7.1 mm (wet layer thickness=50 μm). In addition to the region covered with sintering paste, the silver layer had a peripheral edge region of 0.25 mm width that was free of sintering paste. The copper foil pieces thus provided with a sintering paste on the silver layer were then dried at 110° C. in an air atmosphere for ten minutes, removed from the frame, detached from the transfer film and singularized with separation of the webs by means of laser, wherein substrate arrangements according to Example 1 were obtained.

### 1.2 Example 2

The substrate arrangements according to Example 2 were prepared analogously to the substrate arrangements according to Example 1, but the immersion time of the copper foil pieces in the nitric acid silver nitrate solution (silver content=1.0 g/l) at a temperature of 55° C. was 400 s. This resulted in copper foil pieces with a silver layer arranged on the underside, which had a thickness of 398 nm.

### 1.3 Example 3

The substrate arrangements according to Example 3 were prepared analogously to the substrate arrangements according to Example 1, but the immersion time of the copper foil pieces in the nitric acid silver nitrate solution (silver content=1.0 g/l) at a temperature of 55° C. was 600 s.

This resulted in copper foil pieces with a silver layer arranged on the underside, which had a thickness of 606 nm.

### 1.4 Example 4

The substrate arrangements according to Example 4 were prepared analogously to the substrate arrangements according to Example 1, but the immersion time of the copper foil pieces in the nitric acid silver nitrate solution (silver content=1.0 g/l) at a temperature of 55° C. was 800 s. This resulted in copper foil pieces with a silver layer arranged on the underside, which had a thickness of 793 nm.

### 1.5 Comparative Example 1

The substrate arrangements according to Comparative Example 1 were prepared analogously to the substrate arrangements according to Example 1, but the immersion time of the copper foil pieces in the nitric acid silver nitrate solution (silver content=1.0 g/l) at a temperature of 55° C. was 15 s. This resulted in copper foil pieces with a silver layer arranged on the underside, which had a thickness of 17 nm.

### 1.6 Comparative Example 2

The pretreated copper foil pieces were first electrolytically coated with a 5 μm thick nickel layer on their underside. A 150 nm thick palladium layer was then electrolytically deposited on the nickel layer. Subsequently, a 90 nm thick gold layer was again electrolytically deposited on the palladium layer. This resulted in copper foil pieces that had a coating of nickel, palladium and gold arranged on the underside with a total layer thickness of 5.24 μm.

A silver sinter layer was then applied to the coating (more precisely the gold layer of the coating). For this purpose, a sintering paste (ASP 043-60, Heraeus) was applied by means of stencil printing to a region of 7.1 mm×7.1 mm (wet layer thickness=40 μm). In addition to the region covered with sintering paste, the coating had a peripheral edge region of 0.25 mm width that was free of sintering paste. The copper foil pieces thus provided with a sintering paste on the coating were then dried at 110° C. in an air atmosphere for ten minutes, removed from the frame, detached from the transfer film and singularized with separation of the webs by means of laser, wherein substrate arrangements according to Comparative Example 2 were obtained.

### 1.7 Comparative Example 3

The pretreated copper foil pieces were electrolytically coated with a 1500 nm thick silver layer on their underside.

A silver sinter layer was then applied to the silver layer. For this purpose, a sintering paste (ASP 043-60, Heraeus) was applied by means of stencil printing to a region of 7.1 mm×7.1 mm (wet layer thickness=40 μm). In addition to the region covered with sintering paste, the silver layer had a peripheral edge region of 0.25 mm width that was free of sintering paste. The copper foil pieces thus provided with a sintering paste on the silver layer were then dried at 110° C. in an air atmosphere for ten minutes, removed from the frame, detached from the transfer film and singularized with separation of the webs by means of laser, wherein substrate arrangements according to Comparative Example 3 were obtained.

### 2. Production of Electronic Assemblies

### 2.1 Example 1

To produce an electronic assembly, an arrangement consisting of a base substrate and an electronic component was first created. A commercially available direct-metalized copper-ceramic substrate (DCB; Condura® classic, Heraeus) and, as an electronic component, a silicon chip having the dimensions 8.8 mm×8.8 mm (thickness=70 μm), which had a metalization (NiP/Pd) on the underside and a metalization (NiP/Pd) on the upper side, was used as the base substrate.

A sintering paste (ASP 338-28, Heraeus) was applied to the upper side of the copper-ceramic substrate by means of stencil printing (wet layer thickness=100 μm). The copper-ceramic substrate provided with sintering paste was dried at 100° C. for ten minutes in an air atmosphere and then cooled. The silicon chip was positioned on the pre-dried sintering paste so that the underside of the silicon chip was in contact with the upper side of the copper-ceramic substrate.

Subsequently, the substrate arrangement according to Example 1 (cf. Point 1.1) was positioned on the upper side of the silicon chip, so that the silver sinter layer of the substrate arrangement was in contact with the upper side of the silicon chip.

The structure obtained was then sintered. Sintering was carried out in a sintering press (the Pink company, Wertheim) for a period of three minutes in a nitrogen atmosphere at a pressure of 20 MPa and a temperature of 250° C. An electronic assembly was obtained.

### 2.2 Examples 2-4

Electronic assemblies were also produced using the substrate arrangements of Examples 2-4 (cf., Points 1.2-1.4). This was done analogously to the production of the electronic assembly with the substrate arrangement from Example 1.

### 2.3 Comparative Examples 1-3

Electronic assemblies were also produced using the substrate arrangements of Comparative Examples 1-3 (cf., Points 1.5-1.7). This was done analogously to the production of the electronic assembly with the substrate arrangement from Example 1.

### 3. Evaluation

The substrate arrangements of Examples 1-4 and Comparative Examples 1-3 were examined with regard to their adhesion strength, degree of silver residues and formation of a diffusion zone. The results are shown in Table 1.

### 3.1 Determination of Adhesive Strength

The electronic assemblies produced with the substrate arrangements of Examples 1-4 and Comparative Examples 1-3 were investigated with respect to the adhesive strength of the metal foils on the upper side of the silicon chips. By means of the material testing machine made by Condor Sigma (xyztec bv, Netherlands), the force was measured which had to be applied in order to remove from the upper side of the silicon chips the metal foil connected in an integrally bonded manner to the upper side of the silicon chips. For this purpose, the electronic assemblies produced with the substrate arrangements of Examples 1-4 and Comparative Examples 1-3 were fixed in a screw clamping device and peeled off upward at a peel angle of 90° and at a speed of 1 mm/s. The values given in Table 1 represent the maximum values.

### 3.2 Determination of the Degree of Silver Residue

The metal foils removed during determination of the adhesion strength according to 3.1 were visually examined for silver residues.

### 3.3 Determination of the Formation of a Diffusion Zone

To determine the formation of a diffusion zone, a cut through the electronic assembly was made perpendicular to the metal foil. The cut surface was scanned under a scanning electron microscope in a line scan and the element distribution was measured by means of SEM-EDX. The element signals (in cps, counts per second) were determined as a function of the measuring length (in μm). The element distribution curves thus obtained were then evaluated. The diffusion zone extended from an initial drop in the copper signal to a value of approximately 0 cps (noise floor).

TABLE 1
Results of the examination of the substrate arrangements
of Examples 1-4 and Comparative Examples 1-3.

| | Adhesive strength | Silver | Diffusion zone |
|---|---|---|---|
| | (force in N) | residues | (length in μm) |
| Examples | | | |
| 1 | 15 | High | Approx. 1.0 |
| 2 | 17 | High | Approx. 1.0 |
| 3 | 16 | High | Approx. 1.0 |
| 4 | 17 | High | Approx. 1.0 |
| Comparative | | | |
| examples | | | |
| 1 | 10 | Low | Approx. 0.3 |
| 2 | 12 | Medium | Approx. 0.3 |
| 3 | 13 | Medium | Approx. 1.0, |
| | | | but no diffusion |
| | | | through the entire |
| | | | silver layer |

### 4. Evaluation

The results show that the substrate arrangements according to the invention according to Examples 1-4 are superior to the substrate arrangements according to Comparative Examples 1-3 as regards their adhesive strength, degree of silver residues and formation of a diffusion zone. For example, the connections produced with the substrate arrangements of Examples 1-4 have a significantly increased adhesive strength compared to the connections produced with the substrate arrangements of Comparative Examples 1-3. The metal foils removed during the adhesive strength measurement show a high degree of silver residue. This suggests that the adhesive strength of the connection between the metal foil and the bonding zone is so strong that a tearing of the connection does not occur at the interface between the metal foil and the bonding zone, but in the bonding zone itself. In conjunction with this, a comparison of the diffusion zone lengths indicates that the substrate arrangements according to the invention according to Examples 1-4 make possible a pronounced diffusion of the metal of the metal foil toward the upper side of the electronic component, which causes an increase in adhesive strength. A pronounced diffusion zone can also be achieved with the substrate arrangement according to Comparative Example 3. However, the silver layer of the substrate arrangement appears to act as a diffusion barrier, which prevents diffusion to the upper side of the electronic component and thus does not contribute to increasing the adhesion strength.

### LIST OF REFERENCE NUMERALS

10 substrate arrangement
26 metal foil
23 upper side (metal foil)
24 underside (metal foil)
30 silver sinter layer
40 electronic component
43 upper side (electronic component)
44 underside (electronic component)
50 base substrate
53 upper side (base substrate)
55, 55′ metal layer
56 layer of insulating material
100 electronic assembly

1. A substrate arrangement comprising
(a) a metal foil comprising an upper side and an underside;
(b) a silver layer arranged on the underside of the metal foil; and,
(c) a silver sinter layer arranged on the silver layer; wherein the silver layer has a thickness d(Ag) in the range of 20-1500 nm.

2. The substrate arrangement according to claim 1, wherein the metal foil comprises copper.

3. The substrate arrangement according to claim 1, wherein the metal foil has a thickness d (Me) in the range of 20-400 μm.

4. The substrate arrangement according to claim 1, wherein the silver layer is deposited on the underside of the metal foil without external current.

5. The substrate arrangement according to claim 1, wherein the silver sinter layer comprises a sintering material.

6. The substrate arrangement according to claim 1, wherein the silver sinter layer comprises a pre-dried sintering paste.

7. The substrate arrangement according to claim 1, wherein the ratio R=d(Ag)/d(Me) is less than 0.05.

8. The substrate arrangement according to claim 1, wherein the ratio R=d(Ag)/d(Me) is less than 0.005.

9. The substrate arrangement according to claim 1, wherein the substrate arrangement is designed for connection to at least one electronic component.

10. A method for producing an electronic assembly comprising the steps of
(A) providing a base substrate that comprises an upper side, wherein the base substrate comprises a metal layer;
(B) providing an electronic component that comprises an upper side and an underside;
(C) providing a substrate arrangement according to claim 1;
(D) contacting the upper side of the base substrate with the underside of the electronic component, forming an integrally bonded connection; and,
(E) contacting the upper side of the electronic component with the contacting layer of the substrate arrangement, forming an integrally bonded connection.

11. An electronic assembly which can be produced by a method according to claim 10.

12. The substrate arrangement according to claim 2, wherein the metal foil has a thickness d(Me) in the range of 20-400 μm.
